(19) United States
(12) Patent Application Publication
(10) Pub. No.: US 2017/0133344 A1
(43) Pub. Date: May 11, 2017

(54) SEMICONDUCTOR DEVICE WITH A RESIN LAYER AND METHOD OF MANUFACTURING THE SAME

(71) Applicant: KABUSHIKI KAISHA TOSHIBA, Tokyo (JP)

(72) Inventor: Satoru TAKAKU, Yokohama Kanagawa (JP)

(21) Appl. No.: 15/253,747

(22) Filed: Aug. 31, 2016

(30) Foreign Application Priority Data
Nov. 9, 2015 (JP) 2015-219580

(51) Int. Cl. H01L 23/00; H01L 23/31; H01L 21/66

(52) U.S. Cl. CPC H01L 24/49; H01L 22/32; H01L 23/3121; H01L 24/48; H01L 24/06; H01L 23/3142; H01L 24/09; H01L 2224/06179; H01L 2224/06517; H01L 2224/09517; H01L 2224/09179; H01L 2224/48463; H01L 2224/49179; H01L 2224/48451; H01L 2224/49051; H01L 2924/18301

(57) ABSTRACT

A semiconductor device includes a substrate, a semiconductor chip having a first surface bonded to the substrate and a second surface that is opposite to the first surface and includes a first electrode pad and a second electrode pad thereon, the first electrode pad being electrically connected to a circuit of the semiconductor chip that is operated during operation of the semiconductor device and the second electrode pad being electrically separated from the circuit, a first wire extending between the first electrode pad and a terminal of the substrate that is electrically connected with an external device during operation of the semiconductor device, a second wire extending between the second electrode pad and the substrate, and a resin layer formed over the second surface of the semiconductor chip and covering the first and second wires.

### CROSS-REFERENCE TO RELATED APPLICATION

This application is based upon and claims the benefit of priority from Japanese Patent Application No. 2015-219580, filed Nov. 9, 2015, the entire contents of which are incorporated herein by reference.

### FIELD

Embodiments described herein relate generally to a semiconductor device and a method of manufacturing the same.

### BACKGROUND

Due to induced stresses caused by thermal expansion, resin layers used in semiconductor packages tend to have poor adhesion with surfaces of structures formed from the metal materials or semiconductor materials used in semiconductor chips. For example, heating of a semiconductor package causes the resin layers and the metal materials or the resin layers and the semiconductor materials to expand differently. When resin layers are peeled off from surfaces of metal pads, in particular dummy pads, gaps are formed between the resin layers and the metal pads. Such gaps cause problems, such as corrosion of the metal pads, thereby reducing reliability of the semiconductor package.

### DESCRIPTION OF THE DRAWINGS

FIGS. 1A and 1B are a cross-sectional view and a plan view of a semiconductor package according to an embodiment, respectively.

FIGS. 2A and 2B are a cross-sectional view and a plan view, respectively, of a semiconductor chip during manufacturing of the semiconductor package according to the embodiment.

FIGS. 3A and 3B are a cross-sectional view and a plan view, respectively, of the semiconductor chip in a manufacturing step after the step illustrated in FIGS. 2A and 2B.

FIG. 4 is a cross-sectional view of a semiconductor package in which metal balls are formed a plurality of times.

### DETAILED DESCRIPTION

An embodiment is directed to providing a semiconductor device and a method of manufacturing the same that can prevent a resin layer formed on a semiconductor chip from being peeled off of the semiconductor chip.

In general, according to an embodiment, a semiconductor device includes a substrate, a semiconductor chip having a first surface bonded to the substrate and a second surface that is opposite to the first surface and includes a first electrode pad and a second electrode pad thereon, the first electrode pad being electrically connected to a circuit of the semiconductor chip that is operated during operation of the semiconductor device and the second electrode pad being electrically separated from the circuit, a first wire extending between the first electrode pad and a terminal of the substrate that is electrically connected with an external device during operation of the semiconductor device, a second wire extending between the second electrode pad and the substrate, and a resin layer formed over the second surface of the semiconductor chip and covering the first and second wires.

Hereinafter, an embodiment will be described with reference to the drawings. The present disclosure is not limited to an exemplary embodiment.

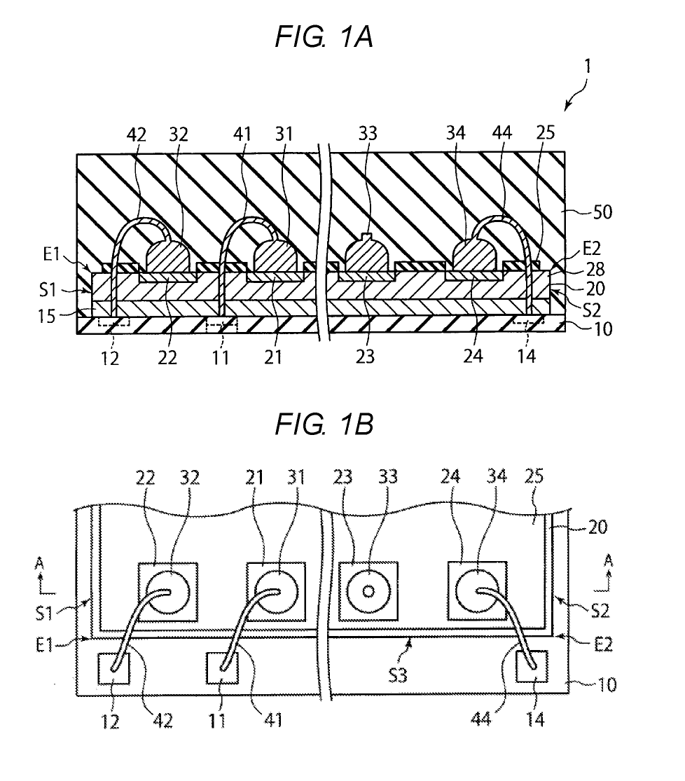

FIGS. 1A and 1B are a cross-sectional view and a plan view of a semiconductor package 1 according to the present embodiment, respectively. The cross-sectional view of FIG. 1 is taken along a line A-A in FIG. 1B. The semiconductor package 1 includes a substrate 10, a semiconductor chip 20, bumps 31 to 34, wires 41 to 44, and a resin layer 50.

The substrate 10 is a member which can electrically connect the semiconductor chip 20 to an external device of the semiconductor package 1, and, for example, a printed substrate or a lead frame. In the present embodiment, the substrate 10 is a printed substrate and includes conductive substrate-side pads 11, 12, and 14. The substrate-side pads 12 and 14 are dummy pads which are not used in normal use of the semiconductor package 1. The substrate-side pads 12 and 14 are not electrically connected to an external device of the semiconductor package 1, and are in an electrically floating state. On the other hand, the substrate-side pad 11 is a pad which is used in normal use of the semiconductor package 1 and electrically connectable to an external device of the semiconductor package 1. Only one substrate-side pad 11 is illustrated in FIGS. 1A and 1B, but a plurality of substrate-side pads 11 may be formed. The number of second electrode pads 22 to 24 is not limited as well. The normal use refers to use of the semiconductor package 1 by a user after the semiconductor package 1 is released in a market.

The semiconductor chip 20 is bonded onto the substrate using an adhesive (die attachment agent) 15. The semiconductor chip 20 includes an electronic circuit (not illustrated) having semiconductor elements (for example, transistors, resistors, and capacitors) formed on the semiconductor substrate 28. The semiconductor chip 20 may be a single semiconductor chip or may be a plurality of semiconductor chips which are stacked. In the present embodiment, the semiconductor chip 20 is assumed to be a single semiconductor chip.

The semiconductor chip 20 includes electrode pads 21 to 24. The first electrode pad 21 is electrically connected to the electronic circuit of the semiconductor chip 20. The second electrode pads 22 to 24 are not electrically connected to the electronic circuit of the semiconductor chip 20 but are electrically connected to a test pattern (not illustrated), which is separately provided from the electronic circuit. The test pattern is a semiconductor element formed in the semiconductor chip 20 in order to verify electric characteristics of the electronic circuit of the semiconductor chip 20 and is not used in normal use. The test pattern is formed between end regions of semiconductor chips which are adjacent to each other in a wafer state or is formed in an empty space on the semiconductor chip. The test pattern is electrically isolated from the electronic circuit used in normal use. Thus, the test pattern is electrically isolated from the electronic circuit of the semiconductor chip 20 and an external device of the semiconductor package 1 and is in the electrically floating state. The second electrode pads 22 and 24 are formed near corner portions E1 and E2 of the semiconductor chip 20. For example, a conductive material such as aluminum is used for the first and second electrode pads 21 to 24.

The semiconductor chip 20 further includes an insulation film 28 formed on surfaces of the semiconductor chip 20. The insulation film 28 covers a surface region of a front surface of the semiconductor chip 20 other than the first and second electrode pads 21 to 24 and end portions of the front surface of the semiconductor chips 20 to protect the electronic circuit of the semiconductor chip 20. The insulation film 28 is not formed at least on the first and second electrode pads 21 to 24, at the end portions of the front surface of the semiconductor chip 20, and on side surfaces and a rear surface of the semiconductor chip 20. For example, polyimide is used for the insulation film 28.

The bumps 31 to 34 are formed on the first and second electrode pads 21 to 24, respectively. For example, the bump 31 is formed on the first electrode pad 21 and electrically connected between the first electrode pad 21 and the first wire 41. The bumps 32 to 34 are formed on the second electrode pads 22 to 24, respectively. The bump 32 is electrically connected between the second electrode pad 22 and the second wire 42. The bump 34 is electrically connected between the second electrode pad 24 and the second wire 44. The bumps 32 and 34 are formed near the corner portions E1 and E2 of the semiconductor chip 20, respectively, similarly to the second electrode pads 22 and 24. The bump 33 is formed on the second electrode pad 23 and connected to no wire. For example, low-resistance metal such as gold, silver, copper, CuAl, or AgAl is used for the bumps 31 to 34.

The wires 41, 42, and 44 are connected between the bumps 31, 32, and 34 and substrate-side pads 11, 12, and 14, respectively. For example, the wire 41 is connected between the first bump 31 and the substrate-side pad 11. One end of the wire 41 is electrically connected to the first electrode pad 21 via the first bump 31, and the other end of the wire 41 is electrically connectable to an external device of the semiconductor package 1 via the substrate-side pad 11. The second wire 42 is connected between the second bump 32 and the substrate-side pad 12. One end of the wire 42 is electrically connected to the second electrode 22 via the second bump 32, and the other end of the wire 42 is connected to the substrate-side pad 12 which is in the electrically floating state. The wire 44 is connected between the second bump 34 and the substrate-side pad 14. One end of the wire 44 is electrically connected to the second electrode 24 via the second bump 34, and the other end of the wire 44 is connected to the substrate-side pad 14 which is in the electrically floating state. The wires 42 and 44 are connected between the second bumps 31 and 34, and the substrate-side pads 12 and 14, respectively, and are in the electrically floating state.

No wire is formed between the bump 33 and the substrate 10. Thus, the bump 33 is connected to the second electrode pad 23 and not connected to the substrate 10. Accordingly, the bump 33 is also in the electrically floating state.

The wires 41, 42, and 44 may be formed of the same material as the bumps 31 to 34. For example, low-resistance metal such as gold, silver, copper, CuAl, or AgAl may be used. In wire bonding, for example, the bump 31 is formed by melting the wire 41 to form a metal ball and connecting the metal ball to an upper surface of the first electrode pad 21 of the semiconductor chip 20. Thereafter, the wire 41 is extended to the substrate-side pad 11 of the substrate 10 so that the wire 41 is connected to the substrate-side pad 11. As a result, the bump 31 is formed on the first electrode pad 21 of the semiconductor chip 20, and the wire 41, which is formed of the same material as the bump 31, is connected between an upper portion of the bump 31 and the substrate-side pad 11 of the substrate 10. The same applies to the bumps 32 and 34 and the wires 42 and 44.

No wire is connected to the bump 33. The bump 33 is formed by melting a forming wire (not shown) to form a metal ball and connecting the metal ball to an upper surface of the electrode pad 23 of the semiconductor chip 20. However, the forming wire is not extended from the bump 33 and is cut or otherwise separated from the bump 33 thereafter. Accordingly, the bump 33 remains on the electrode pad 23 as a bump not connected to the substrate 10.

The resin layer 50 is formed around the semiconductor chip 20, the wires 41, 42, and 43, and the bumps 31 to 34 to seal these components. The resin layer 50 includes, for example, epoxy resin, a curing agent, a curing accelerator, a filler, and an additive.

As described above, in the present embodiment, the bumps 32 to 34 are formed on the second electrode pads 22 to 24, which are not electrically connected to the outside of the semiconductor package 1. Further, the second wires 42 and 44 are connected to the bumps 32 and 34 and the substrate-side pads 12 and 14 of the substrate 10, respectively. As described above, the substrate-side pads 12 and 14 are dummy pads that are not electrically connected to an external device of the semiconductor package 1. The second electrode pads 22 and 24 are connected to the test pattern on the semiconductor chip 20 and are in the electrically floating state in normal use. That is, the second electrode pads 22 and 24 are dummy pads. Thus, the substrate-side pad 12, the wire 42, the bump 32, and the second electrode pad 22 are in the electrically floating state. The substrate-side pad 14, the wire 44, the bump 34, and the second electrode pad 24 are also in the electrically floating state as in the substrate-side pad 12, the wire 42, the bump 32, and the second electrode pad 22.

In this way, according to the present embodiment, the second electrode pads 22 and 24 and the second wires 42 and 44 are formed as dummies near the corner portions E1 and E2 (corner portions) of the semiconductor chip 20. The resin layer 50 is also formed around the second electrode pads 22 and 24 and the second wires 42 and 44. The resin layer 50 is less likely to be peeled from the surfaces of the second electrode pads 22 and 24 because of an anchor effect of the second electrode pads 22 and 24 and the second wires 42 and 44. That is, the bumps 32 and 34 and the second wires 42 and 44 have the anchor effect with regard to adhesion between the second electrode pads 22 and 24 and the resin layer 50, and thus adhesion between the resin layer 50 and the semiconductor chip 20 at the corner portions of the semiconductor chip 20 is improved, thereby preventing or discouraging the resin layer 50 from being peeled.

It is not necessary to carry out wire bonding on the electrode pads which are not used in normal use and are in the electrically floating state. That is, it is not necessary to provide the bumps and the wires for such electrode pads. However, the resin layer 50 tends to be peeled off from surfaces of flat dummy pads not subjected to wire bonding, and as a result a gap tends to be formed between the resin layer 50 and the flat dummy pads. Stress in the resin layer 50 due to thermal contraction of the resin tends to be concentrated on a portion in which a volume ratio of the resin layer 50 with respect to the other members is large. For example, stress in the resin layer 50 tends to be concentrated on the portion of the dummy pad on which no bump is formed or the corner portions of the semiconductor chip 20.

In contrast, according to the present embodiment, the bumps 32 and 34 are formed on the second electrode pads 22 and 24, which are in the electrically floating state. As the shapes above the second electrode pads 22 and 24 become complicated, the adhesion between the resin layer 50 and the semiconductor chip 20 at the corner portions of the semiconductor chip 20 is improved, thereby discouraging the resin layer 50 from delaminating or being peeled off. Further, according to the present embodiment, the wires 42 and 44 are formed between the bumps 32 and 34 and the substrate-side pads 12 and 14, respectively. As a result, the shapes near the corner portions E1 and E2 of the semiconductor chip 20 become complicated, and the wires 42 and 44 are physically connected between the bumps 32 and 34 and the substrate-side pads 12 and 14, respectively. For that reason, the anchor effect (adhesion) between the resin layer 50 and the semiconductor chip 20 at the corner portions E1 and E2 of the semiconductor chip 20 is further improved, thereby further preventing or discouraging the resin layer 50 from being peeled off at the corner portions E1 and E2 of the semiconductor chip 20. Further, by forming the bumps 32 and 34 and the wires 42 and 44, the volume ratio of the resin layer 50 with respect to the other members at the corner portions E1 and E2 of the semiconductor chip 20 and on the second electrode pads 22 and 24 is reduced. As a result, internal stress in the resin layer 50 caused by contraction of the resin layer 50 is reduced, thereby further preventing or discouraging the resin layer 50 from being peeled off at the corner portions E1 and E2 of the semiconductor chip 20 and portions above the second electrode pads 22 and 24.

An insulation film 25 is formed on the upper surface of the semiconductor chip 20. For example, an insulation material such as polyimide is used for the insulation film 25. As adhesion between the insulation film 25 and the resin layer 50 is strong, and the resin becomes less likely to be peeled off. However, the insulation film 25 is not formed on the electrode pads 21 to 24, at the corner portions E1 and E2 of the semiconductor chip 20, and on side surfaces S1 to S3 of the semiconductor chip 20. The reason why the insulation film 25 is not formed at the corner portions E1 and E2 of the semiconductor chip 20 and on side surfaces S1 to S3 of the semiconductor chip 20 is that the insulation film 25 is cut along with a wafer by wafer dicing to divide a wafer that includes plurality of semiconductor chips into individual chips after the insulation film 25 is formed on the wafer. For that reason, a semiconductor substrate (for example, silicon) is exposed at the corner portions E1 and E2 and on the side surfaces S1 to S3 of the semiconductor chip 20. Although not illustrated, the insulation film 25 is not formed at corner portions other than the corner portions E1 and E2 of the semiconductor chip 20 and a side surface of the semiconductor chip 20 opposite to the side surface S3. The adhesion between the resin layer 50 and a semiconductor material such as silicon is weaker than adhesion between the resin layer 50 and the insulation film 25. For that reason, by forming the wires 42 and 44 between the bumps 32 and 34 and the substrate-side pads 12 and 14, respectively, the anchor effect (adhesion) between the resin layer 50 and the semiconductor chip 20 at the corner portions E1 and E2 and on the side surfaces S1 and S3 of the semiconductor chip 20 is further improved, and the resin layer 50 becomes less likely to be peeled off from the corner portions E1 and E2 and the side surfaces S1 to S3 of the semiconductor chip 20. The bumps 32 and 34 are formed on the second electrode pads 22 and 24 of the semiconductor chip 20, respectively, and are not connected to the substrate 10. However, the wires 42 and 44 are physically connected between the substrate-side pads 12 and 14 and the bumps 32 and 34 on the semiconductor chip 20, respectively. For example, as illustrated in FIG. 1B, the wires 42 and 44 are extended from the bumps 32 and 34 to the substrate-side pads 12 and 14, respectively, across the vicinities of the corner portions E1 and E2 and the side surfaces S1 to S3 of the semiconductor chip 20, respectively. By forming the wires 42 and 44 as well as the bumps 32 and 34, it is possible to improve adhesion between the resin layer 50 and the semiconductor chip 20 at the corner portions E1 and E2 and the side surfaces S1 to S3 of the semiconductor chip 20.

The shapes of the bumps 32 to 34 are not limited to a particular shape or morphology, but the anchor effect (adhesion) generally increases as the surface shapes become more complicated. Similarly, while the shapes of the wires 42 to 44 are not limited to any particular configuration or shape, the anchor effect (adhesion) generally increases as the surface shapes become more complicated.

The bump 33 also provides a similar anchor effect. The bump 33 is not formed at the corner portion of the semiconductor chip 20, but is formed near the side surface S3 of the semiconductor chip 20. For that reason, although no wire is formed on the bump 33, the anchor effect is considered to be caused by the bump 33 sufficiently. In this way, the dummy wires 42 and 44 for the purpose of causing the anchor effect are formed on the bumps 32 and 34 on the dummy second electrode pads 22 and 24 formed at the corner portions E1 and E2 of the semiconductor chip 20, and no wire may be formed in the bump 33 on the other dummy electrode pad 23, which is not at corner portions of the semiconductor chip 20. Of course, a wire, such as the forming wire employed to form the bump 33, may be formed between the bump 33 and the substrate 10. In that case, it is possible to further improve the anchor effect and carry out the wiring bonding for the electrode pad 23 in the same manner as the wiring bonding for the other electrode pads 21, 22, and 24. Thus, in this case, the wire bonding process can be relatively simplified.

Next, a method of manufacturing the semiconductor package 1 according to the present embodiment will be described.

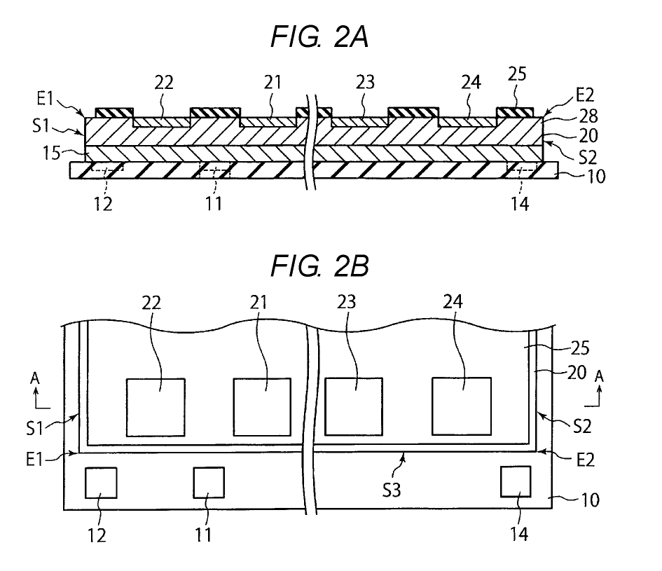

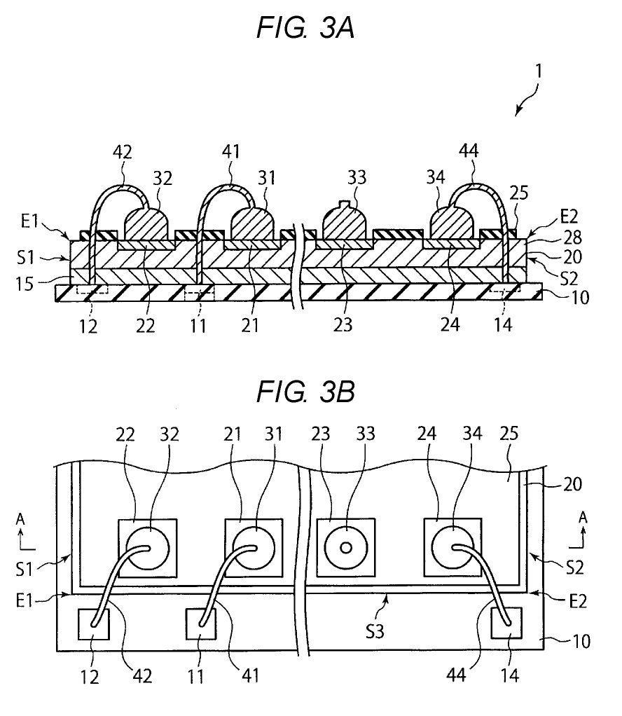

FIGS. 2A to 3B are cross-sectional views and plan views of the semiconductor chip 20 to illustrate a method of manufacturing the semiconductor package 1 according to the present embodiment. FIG. 2A is a cross-sectional view taken along a line A-A in FIG. 2B. FIG. 3A is a cross-sectional view taken along a line A-A in FIG. 3B.

First, as illustrated in FIGS. 2A and 2B, the semiconductor chip 20 is mounted on the substrate 10. A sheet-shaped adhesive sheet (die attachment sheet) 15 is formed on the rear surface of the semiconductor chip 20, and then the semiconductor chip 20 is bonded to the substrate 10 by placing the rear surface of the semiconductor chip 20 at a predetermined position of the substrate 10. Alternatively, by supplying a liquid adhesive 15 on the substrate 10 and mounting the semiconductor chip 20 on the adhesive 15, the semiconductor chip 20 may be bonded to the substrate 10.

Next, as illustrated in FIGS. 3A and 3B, wire bonding is carried out. A method for the wire bonding is not particularly limited. For example, in the present embodiment, wires of low-resistance metal such as gold, silver, copper, CuAl, or AgAl are used for the wires 41 to 44, and each of the wires is melted into a metal ball. The metal ball corresponding to the wire 41 is formed on the first electrode pad 21 of the semiconductor chip 20. As a result, the bump 31 is formed. Next, the wire 41 is extended from the bump 31 to the substrate-side pad 11 of the substrate 10, and the wire 41 is connected to the substrate-side pad 11. As a result, the wire 41 is electrically and physically connected between the bump 31 on the first electrode pad 21 of the semiconductor chip 20 and the substrate-side pad 11 of the substrate 10.

The wire bonding is carried out also on the bumps 32 and 34. For the bump 33, the wire is cut off from the bump 33 after a metal ball is formed on the electrode pad 23 of the semiconductor chip 20 by melting the wire. As a result, the bump 33 from which no wire is extended is formed on the electrode pad 23.

In this way, the first wire 41 is electrically connected between the first electrode pad 21 that is electrically connected to the electronic circuit of the semiconductor chip and the substrate-side pad 11 that is electrically connectable to the external device of the semiconductor package 1. The second wires 42 and 44 are electrically connected between the second electrode pads 22 and 24 that are formed in the semiconductor chip 20 and the substrate-side pads 12 and 14 that are not electrically connected to an external device of the semiconductor package 1, respectively.

After the bump 31 is formed, the wire 41 is electrically connected between the bump 31 and the substrate-side pad 11 of the substrate 10. After the bump 32 is formed, the wire 42 is electrically connected between the bump 32 and the substrate-side pad 12 of the substrate 10. However, a sequence in which the bumps 31 to 34 and the wires 41, 42, and 44 are formed is not particularly limited.

Next, as illustrated in FIGS. 1A and 1B, the resin layer 50 is formed to seal the peripheries of the semiconductor chip 20, the bumps 31 to 34, and the first and second wires 41, 42, and 44. As a result, the semiconductor package 1 according to the present embodiment is formed.

In this way, according to the present embodiment, the second electrode pads 22 and 24, from which the second wires 42 and 44 extend respectively, are formed as dummy pads at the corner portions E1 and E2 (corner portions) of the semiconductor chip 20. The anchor effect of the bumps 32 and 34 and the second wires 42 and 44 improves the adhesion between the resin layer 50 and the semiconductor chip 20 at the corner portions of the semiconductor chip 20, thereby preventing or discouraging the resin layer 50 from being peeled off. The second electrode pads 22 and 24 and the second wires 42 and 44 may be formed in portions of the semiconductor chip 20 other than the corner portions E1 and E2. Even in this case, it is possible to improve the adhesion between the resin layer 50 and the semiconductor chip 20, thereby preventing or discouraging the resin layer 50 from being peeled off.

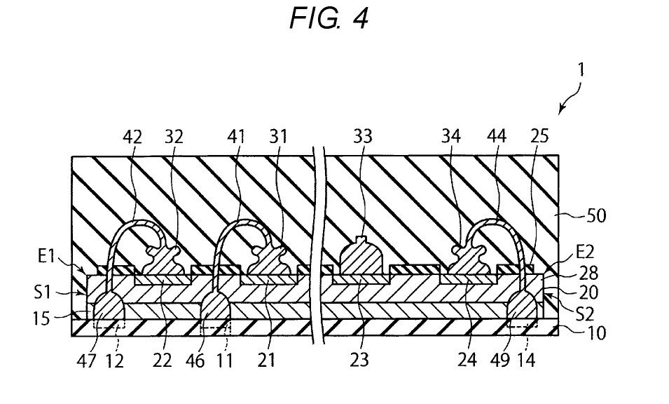

To form the bumps 31 to 34, forming of the metal ball may be carried out on the electrode pads 21 to 24 only once as shown in FIG. 1 or a plurality of times. FIG. 4 is a cross-sectional view of the semiconductor package 1 when forming of the metal ball is carried out a plurality of times. In this case, lower portions of the bumps 31 to 34 are formed on the electrode pads 21 to 24, and the wires 41, 42, and 44 are subsequently cut. Thereafter, bumps 46, 47, and 49 are formed on the substrate-side pads 11, 12, and 14, respectively, and then the wires 41, 42, and 44 are extended up to the bumps 31, 32, and 34, respectively, so that the metal balls are formed on the lower portion of the bumps 31, 32, and 34. In this way, by forming the metal balls on the same electrode pads 21 to 24 a plurality of times, as illustrated in FIG. 4, the shapes of the bumps 31 to 34 become relatively complicated. As a result, it is possible to further improve the anchor effect.

In the present embodiment, the wires 41, 42, and 44 are extended from the bumps 31, 32, and 34, respectively, on the side of the semiconductor chip 20 to the substrate-side pads 11, 12, and 14, respectively. That is, after the bump 31 is formed on the first electrode pad 21, the wire 41 is extended from the semiconductor chip 20 to the substrate 10 (forward bonding).

Alternatively, instead of the forward bonding, after the bumps 31 to 34 are formed on the first electrode pads 21 to 24, respectively, the wires 41, 42, and 44 may be extended from the substrate 10 to the semiconductor chip 20 and connected to the bumps 31, 32, and 34 (reverse bonding). In this way, a wire bonding method may be either the forward bonding or the reverse bonding.

In the forward bonding, wires are extended from bumps that are formed in advance. In the reverse bonding, however, wires are cut from bumps after the bumps are formed. Thereafter, different wires are connected to a substrate, and then the different wires are extended towards a semiconductor chip and connected to the bumps. In this way, in the reverse bonding, the bumps are connected to the different wires after the wires are cut from the bumps. For that reason, the bumps can be formed in complicated shapes. Thus, the reverse bonding may be more preferable than the forward bonding in consideration of the anchor effect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a semiconductor chip having a first surface bonded to the substrate and a second surface that is opposite to the first surface and includes a first electrode pad and a second electrode pad thereon, the first electrode pad being electrically connected to a circuit of the semiconductor chip that is operated during operation of the semiconductor device and the second electrode pad being electrically separated from the circuit;
a first wire extending between the first electrode pad and a terminal of the substrate that is electrically connected with an external device during operation of the semiconductor device;
a second wire extending between the second electrode pad and the substrate; and
a resin layer formed over the second surface of the semiconductor chip and covering the first and second wires.

2. The semiconductor device according to claim 1, wherein
a first bump is formed at an end of the first wire, and the first bump is formed on the first electrode pad, and
a second bump is formed at an end of the second wire, and the second bump is formed on the second electrode pad.

3. The semiconductor device according to claim 2, wherein
the first bump is formed of a same material as a material of the first wire, and
the second bump is formed of a same material as a material of the second wire.

4. The semiconductor device according to claim 2, wherein
an opposite end of the second wire is connected to a second terminal of the substrate, and a third bump is formed at the opposite end of the second wire.

5. The semiconductor device according to claim 1, further comprising:
an insulation film formed on a region of the second surface of the semiconductor chip, the insulation film not being formed on the first and second electrode pads and an end region of the second surface.

6. The semiconductor device according to claim 5, wherein
the insulation film is formed of polyimide.

7. The semiconductor device according to claim 1, wherein
the semiconductor chip includes a test pattern that is not operated during operation of the semiconductor device, and
the second electrode pad is electrically connected to the test pattern.

8. The semiconductor device according to claim 1, wherein
the first and second electrode pads are formed adjacent to and along an edge of the semiconductor chip.

9. The semiconductor device according to claim 1, wherein
the second electrode pad is formed at a corner of the semiconductor chip.

10. The semiconductor device according to claim 1, wherein
the second electrode pad and the second wire are electrically floating.

11. The semiconductor device according to claim 1, wherein
the semiconductor chip further includes a third electrode pad on the second surface, a bump that is formed on the third electrode pad from a forming wire and is separated from the forming wire, and
the resin layer covers also the bump formed on the third electrode pad.

12. A semiconductor device, comprising:
a substrate;
a semiconductor chip having a first surface bonded to the substrate and a second surface that is opposite to the first surface and includes a first electrode pad and a second electrode pad thereon, the first electrode pad being electrically connected to a circuit of the semiconductor chip that is operated during operation of the semiconductor device and the second electrode pad being electrically separated from the circuit;
a wire extending between the first electrode pad and a terminal of the substrate that is electrically connected with an external device during operation of the semiconductor device;
a bump that is formed on the second electrode pad from a forming wire and is separated from the forming wire; and
a resin layer formed over the second surface of the semiconductor chip and covering the bump and the wire extending between the first electrode pad and the terminal.

13. The semiconductor device according to claim 12, wherein
an upper bump is formed at an end of the wire extending between the first electrode pad and the terminal, and the upper bump is formed on the first electrode pad.

14. The semiconductor device according to claim 12, further comprising:
an insulation film formed on a region of the second surface of the semiconductor chip, the insulation film not being formed on the first and second electrode pads and an end region of the second surface.

15. The semiconductor device according to claim 14, wherein
the insulation film is formed of polyimide.

16. The semiconductor device according to claim 12, wherein
the first and second electrode pads are formed adjacent to and along an edge of the semiconductor chip.

17. The semiconductor device according to claim 12, wherein
the second electrode pad is formed at a corner of the semiconductor chip.

18. The semiconductor device according to claim 12, wherein
the second electrode pad and the bump that is formed on the second electrode pad are electrically floating.

19. A method for manufacturing a semiconductor device, comprising:
bonding a first surface of a semiconductor chip on a substrate, the semiconductor chip having a second surface that is opposite to the first surface and includes a first electrode pad and a second electrode pad thereon, the first electrode pad being electrically connected to a circuit of the semiconductor chip that is operated during operation of the semiconductor device and the second electrode pad being electrically separated from the circuit;
forming a first wire between the first electrode pad and a terminal of the substrate that is electrically connected with an external device during operation of the semiconductor device;
forming a second wire between the second electrode pad and the substrate; and
forming a resin layer over the second surface of the semiconductor chip so as to cover the first and second wires.

20. The method according to claim 19, further comprising:
forming a first bump at an end of the first wire during forming of the first wire, the first bump being formed on the first electrode pad, and
forming a second bump at an end of the second wire during forming of the second wire, the second bump being formed on the second electrode pad.
